(19) United States
(12) Patent Application Publication
(10) Pub. No.: US 2026/0319264 A1
(43) Pub. Date: Oct. 15, 2026

(54) LIGHT IRRADIATION APPARATUS AND EXPOSURE APPARATUS

(71) Applicant: SCREEN Holdings Co., Ltd., Kyoto (JP)

(72) Inventor: Takao CHICHIBU, Kyoto-shi, Kyoto (JP)

(21) Appl. No.: 19/108,527

(22) PCT Filed: Jun. 12, 2023
(86) PCT No.: PCT/JP2023/021688

§ 371 Date: Mar. 4, 2025

(30) Foreign Application Priority Data
Sep. 9, 2022 (JP) 2022-143487

(51) Int. Cl. G02B 27/12; G03F 7/00

(52) U.S. Cl. CPC G02B 27/12; G03F 7/70025; G03F 7/70291

(57) ABSTRACT

In a light irradiation apparatus according to this invention, an illumination optical system includes an incident angle conversion part including a first lens and a second lens arranged in such a positional relation as to form a beam expander, a split lens part having a plurality of lenses arrayed in a direction perpendicular to an optical axis, for splitting light emitted from the incident angle conversion part by the plurality of lenses, an optical path length difference generation part having a plurality of light-transmitting parts which have different optical path lengths and are arrayed in the direction perpendicular to the optical axis, for causing the lights which have passed through the plurality of lenses to enter the plurality of light-transmitting parts, respectively, and a condensing lens part for superimposing irradiation regions of the lights emitted from the plurality of light-transmitting parts on an irradiated surface.

### TECHNICAL FIELD

This invention relates to a technique for exposing a substrate such as a semiconductor substrate, a semiconductor package substrate, a printed circuit board, a glass substrate, or the like to draw a pattern on the substrate.

### BACKGROUND

There is an exemplary technique for forming a pattern such as a wiring pattern or the like on a substrate, where a light beam modulated in accordance with exposure data is caused to be incident on a photosensitive layer formed on a surface of a substrate, to thereby expose the photosensitive layer. As the substrate, various substrates such as a semiconductor substrate, a printed circuit board, a semiconductor package substrate, a glass substrate, and the like are applicable. Patent Literature 1, for example, discloses a drawing apparatus which modulates a laser light beam (line beam) having a flattened beam spot by using a light modulator and causes the modulated line beam to be incident on a substrate, to thereby perform drawing on the substrate and a light irradiation apparatus used as a light source thereof. In this technique, in order to generate a high-intensity line beam having a uniform intensity distribution, laser lights emitted from a plurality of laser light sources (laser diodes) are combined to form a single line beam.

Specifically, lights are emitted from the plurality of laser light sources which are arranged so that respective directions of outgoing lights are included in the same plane, toward one point in the plane. On an optical path thereof, a split lens, an optical path length difference generation part, a condensing lens, and the like are arranged in order. By the action of this optical system, generated is a line beam having a longitudinal direction which is a direction in parallel to the above-described plane, whose spread is narrowed in a direction perpendicular to this longitudinal direction. The optical path length difference generation part is provided to suppress interference caused when the laser lights which are coherent lights are combined.

### CITATION LIST

### Patent Literature

[PTL 1] Patent Publication No. 6383166

### SUMMARY

### Technical Problem

In order to further increase the light intensity, for example, it is considered to increase the number of laser light sources to be provided. In such a case, components of light which enter the split lens at a large incident angle increase. Then, the lights outgoing from the split lens and entering the optical path length difference generation part have various angular components. The lights entering the split lens and the optical path length difference generation part at a large incident angle sometimes exit from side surfaces of these optical elements. There arises a problem that the intensity of the final line beam cannot be sufficiently increased and the uniformity thereof is deteriorated due to such dissipation of the light.

In order to avoid this problem, it is necessary to reduce a spread angle of the incident lights with respect to the split lens to be small. There is a possible method, for example, where a distance between the light source and the split lens is increased. In such a case, however, there arises a further problem that the entire length of the optical path becomes longer and the apparatus is disadvantageously upsized.

### Solution to Problem

This invention is intended to solve the above-described problem, and it is an object of this invention to provide a technique for suppressing dissipation of light emitted from a plurality of laser light sources without increasing an optical path length in a light irradiation apparatus which combines laser light beams generated by using a plurality of light sources into a single beam and emits the single beam and an exposure apparatus using this light irradiation apparatus.

A light irradiation apparatus in accordance with this invention includes a plurality of laser light sources arranged so that respective centerlines of outgoing lights thereof are included in the same plane and intersect at one point in the plane and an illumination optical system for combining laser lights emitted from the plurality of laser light sources to form a single laser light beam and emitting the single laser light beam onto an irradiated surface. Then, the illumination optical system has an incident angle conversion part including a first lens arranged at a position on which respective lights emitted from the plurality of laser light sources are incident and a second lens arranged in such a positional relation as to form a beam expander with the first lens, a split lens part having a plurality of lenses arrayed in a direction perpendicular to an optical axis of the incident angle conversion part and along the plane, for splitting light emitted from the incident angle conversion part by the plurality of lenses, an optical path length difference generation part having a plurality of light-transmitting parts which have different optical path lengths and are arrayed in the direction perpendicular to the optical axis, for causing the lights which have passed through the plurality of lenses to enter the plurality of light-transmitting parts, respectively, and a condensing lens part for superimposing irradiation regions of the lights emitted from the plurality of light-transmitting parts on the irradiated surface.

In this invention having such a configuration, the incident angle conversion part is provided between the plurality of laser light sources for emitting lights from various directions in a single plane toward one point in the plane and the split lens part. In the incident angle conversion part, the first lens and the second lens are arranged in such a positional relation as to form a beam expander. In general, the beam expander is used for the purpose of causing collimated light to be incident along an optical axis thereof to enlarge or reduce a beam diameter of the collimated light. On the other hand, in the incident angle conversion part of the present invention, since the laser lights are incident from various directions, some lights are incident even from a direction having a tilt relative to the optical axis.

Though described later in detail, with such a configuration, it is possible to reduce the spread angle of the lights entering the split lens as compared with the case where the incident angle conversion part is not provided. In other words, the incident angle conversion part has an action of reducing the incident angle at the time when the light emitted from each laser light source is incident on the split lens. Thus, the incident angle conversion part can produce the same effect as that in the case where the distance between the laser light source and the split lens is increased, without increasing the actual distance.

Therefore, it is possible to achieve a dissipation suppressing effect of light from the split lens and the optical path length difference generation part, which can be obtained by reducing the incident angle of light entering the split lens, without increasing the optical path length.

Further, the incident angle conversion part also has an action as a beam expander. Therefore, it is possible to generate a light beam having a spot size in accordance with the size of the split lens from a light beam emitted from each laser light source and cause the generated light beam to enter the split lens. For this reason, it is possible to cause light to uniformly enter a plurality of lenses constituting the split lens.

### Advantageous Effects of Invention

As described above, according to the present invention, the incident angle conversion part formed by combining two lenses is provided on the optical path leading from the plurality of laser light sources to the split lens. It is thereby possible to prevent dissipation of light due to incidence of the light onto the split lens at a large incident angle without increasing the optical path length.

The above and further objects and novel features of the invention will more fully appear from the following detailed description when the same is read in connection with the accompanying drawing. It is to be expressly understood, however, that the drawing is for purpose of illustration only and is not intended as a definition of the limits of the invention.

### BRIEF DESCRIPTION OF DRAWINGS

FIG. 1 is an elevational view schematically showing an outline configuration of an exposure apparatus in accordance with the present invention;

FIG. 2 is a block diagram showing an exemplary electrical configuration included in the exposure apparatus of FIG. 1;

FIG. 3 is a view showing an outline configuration of a light irradiation part;

FIG. 4 is a view schematically showing an exemplary detailed configuration included in an exposure head;

FIG. 5A is a view showing an outline configuration of a laser emission part;

FIG. 5B is a view showing an outline configuration of the laser emission part;

FIG. 6 is a light ray diagram showing an overall configuration of an illumination optical system and an optical path of light beams;

FIG. 7A is a view showing a more detailed configuration and an action of an incident angle conversion part;

FIG. 7B is a view showing a more detailed configuration and an action of the incident angle conversion part;

FIG. 8A is a light ray diagram showing light passing through a split lens and an optical path length difference generation part;

FIG. 8B is a light ray diagram showing the light passing through the split lens and the optical path length difference generation part; and

FIG. 9 is a view showing a relation between incident light on the incident angle conversion part and that on the split lens.

### DESCRIPTION OF EMBODIMENTS

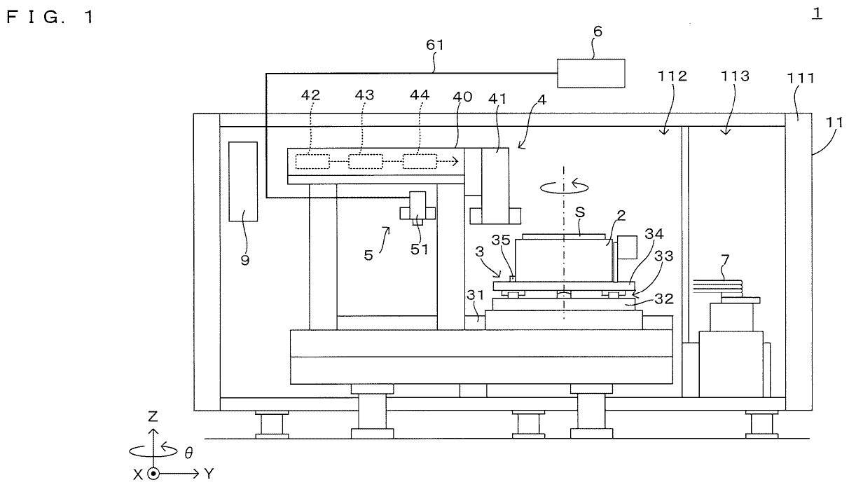

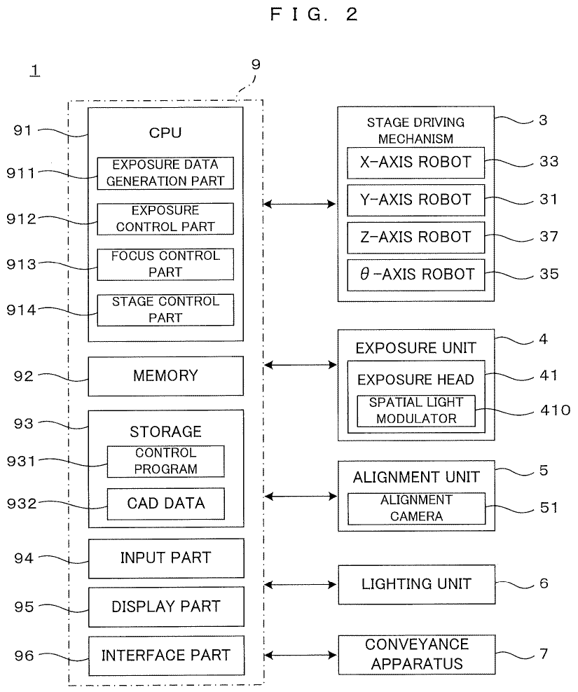

FIG. 1 is an elevational view schematically showing an outline configuration of an exposure apparatus in accordance with the present invention, and FIG. 2 is a block diagram showing an exemplary electrical configuration included in the exposure apparatus of FIG. 1. In FIG. 1 and the following figures, an X direction which is a horizontal direction, a Y direction which is a horizontal direction orthogonal to the X direction, a Z direction which is a vertical direction and a rotation direction θ about a rotation axis in parallel to the Z direction are shown as appropriate.

The exposure apparatus 1 irradiates a substrate S (substrate to be exposed) on which a layer of photosensitive material such as a resist or the like with laser light of predetermined pattern, to thereby draw the pattern on the photosensitive material. As the substrate S, various substrates such as a semiconductor package substrate, a printed circuit board, a glass substrate for any one of various displays, a semiconductor substrate, and the like are applicable.

The exposure apparatus 1 includes a main body 11, and the main body 11 is constituted of a main body frame 111 and a cover panel (not shown) attached to the main body frame 111. Then, both inside and outside the main body 11, various constituent elements of the exposure apparatus 1 are arranged.

The inside of the main body 11 of the exposure apparatus 1 is divided into a processing area 112 and a transferring area 113. In the processing area 112, mainly, a stage 2, a stage driving mechanism 3, an exposure unit 4, and an alignment unit 5 are arranged. Further, outside the main body 11, disposed is a lighting unit 6 for supplying illumination light to the alignment unit 5. In the transferring area 113, disposed is a conveyance apparatus 7 such as a conveyor robot or the like for loading and unloading the substrate S into/from the processing area 112. Furthermore, inside the main body 11, a controller 9 is disposed. The controller 9 is electrically connected to the constituent elements of the exposure apparatus 1 and controls operations of these constituent elements.

The conveyance apparatus 7 disposed in the transferring area 113 inside the main body 11 receives an unprocessed substrate S from an external conveyance apparatus or a substrate storage apparatus not shown and loads the unprocessed substrate S into the processing area 112 (loading). Further, the conveyance apparatus 7 unloads the processed substrate S from the processing area 112 and puts the processed substrate S outside (unloading). Loading of the unprocessed substrate S and unloading of the processed substrate S are performed by the conveyance apparatus 7 in response to a command from the controller 9.

The stage 2 has a flat plate-like outer shape and holds the substrate S placed on an upper surface thereof in a horizontal posture. On the upper surface of the stage 2, a plurality of suction holes (not shown) are formed and a negative pressure (suction pressure) is given to these suction holes. The substrate S placed on the stage 2 is thereby fixed on the upper surface of the stage 2. This stage 2 is driven by the stage driving mechanism 3.

The stage driving mechanism 3 is an X-Y-Z-θ driving mechanism for moving the stage 2 in the Y direction (main scanning direction), the X direction (sub-scanning direction), the Z direction, and the rotation direction θ (yaw direction). The stage driving mechanism 3 has a Y-axis robot 31 which is a single axis robot extending in the Y direction, a table 32 driven in the Y direction by the Y-axis robot 31, an X-axis robot 33 which is a single axis robot extending in the X direction on the upper surface of the table 32, a table 34 driven in the X direction by the X-axis robot 33, and a θ-axis robot 35 for driving the stage 2 supported on the upper surface of the table 34 in the rotation direction θ with respect to the table 34.

Therefore, the stage driving mechanism 3 can drive the stage 2 in the Y direction by a Y-axis servo motor included in the Y-axis robot 31, drive the stage 2 in the X direction by an X-axis servo motor included in the X-axis robot 33, and drive the stage 2 in the rotation direction θ by a θ-axis servo motor included in the θ-axis robot 35. These servo motors are not shown. Further, the stage driving mechanism 3 can drive the stage 2 in the Z direction by a Z-axis robot 37 not shown in FIG. 1. This stage driving mechanism 3 operates the Y-axis robot 31, the X-axis robot 33, the θ-axis robot 35, and the Z-axis robot 37 in response to the command from the controller 9, to thereby move the substrate S placed on the stage 2.

The exposure unit 4 has an exposure head 41 arranged above the substrate S on the stage 2 and a light irradiation part 40 which includes a light source driving part 42, a laser emission part 43, and an illumination optical system 44 and emits laser light to the exposure head 41. A plurality of exposure units 4 may be provided at different positions in the X direction.

The laser light outputted from the laser emission part 43 by an operation of the light source driving part 42 is emitted to the exposure head 41 through the illumination optical system 44. The exposure head 41 uses a spatial light modulator (hereinafter, referred to simply as a “light modulator”) 410 to modulate the laser light emitted from the light irradiation part and causes the modulated laser light to be incident on the substrate S being moved immediately therebelow. By exposing the substrate S with the laser light beam thus, a pattern is drawn on the substrate S (exposure operation).

The alignment unit 5 has an alignment camera 51 disposed above the substrate S on the stage 2. This alignment camera 51 has a lens barrel, an objective lens, and a CCD image sensor and picks up an image of an alignment mark provided on an upper surface of the substrate S being moved immediately therebelow. The CCD image sensor included in the alignment camera 51 is formed of, for example, an area image sensor (two-dimensional image sensor).

The lighting unit 6 is connected to the lens barrel of the alignment camera 51 through an optical fiber 61 and supplies illumination light to the alignment camera 51. The illumination light guided by the optical fiber 61 extending from the lighting unit 6 is guided onto the upper surface of the substrate S through the lens barrel of the alignment camera 51, and reflected light from the substrate S enters the CCD image sensor through the objective lens. An image of the upper surface of the substrate S is thereby picked up and a pickup image thereof is acquired. The alignment camera 51 is electrically connected to the controller 9, and acquires the pickup image in response to the command from the controller 9 and sends this pickup image to the controller 9.

The controller 9 acquires a position of the alignment mark indicated by the pickup image captured by the alignment camera 51. Further, the controller 9 controls the exposure unit 4 on the basis of the position of the alignment mark, to adjust a pattern of the laser light emitted onto the substrate S from the exposure head 41 in the exposure operation. Then, the controller 9 causes the exposure head 41 to emit the laser light modulated in accordance with the pattern to be drawn onto the substrate S, to thereby draw the pattern on the substrate S.

The controller 9 achieves various processings by controlling operations of the above-described units. For this purpose, the controller 9 includes a CPU (Central Processing Unit) 91, a memory (RAM) 92, a storage 93, an input part 94, a display part 95, an interface part 96, and the like. The CPU 91 reads out a control program 931 stored in the storage 93 in advance and executes the control program 931, to thereby perform various operations described later. The memory 92 is used for an arithmetic operation performed by the CPU 91 or stores therein data generated as a result of the arithmetic operation in the short term. The storage 93 stores therein various data and control programs in the long term. Specifically, the storage 93 is a nonvolatile storage such as a flash memory storage device, a hard disk drive device, or the like. The storage 93 stores therein, for example, CAD (Computer Aided Design) 932 which are design data representing a content of a pattern to be drawn, as well as the control program 931 to be executed by the CPU 91.

The input part 94 receives an operation input from a user, and for this purpose, has an appropriate input device (not shown), such as a keyboard, a mouse, a touch panel, or the like. The display part 95 displays and outputs various information to inform the user of the information, and for this purpose, has an appropriate display device, such as a liquid crystal display panel. The interface part 96 administers communication with an external device. The interface part 96 serves, for example, when the exposure apparatus 1 receives the control program 931 and the CAD data 932 from the outside. For this purpose, the interface part 96 may include a function of reading data out from an external recording medium.

The CPU 91 executes the control program 931. Function blocks such as an exposure data generation part 911, an exposure control part 912, a focus control part 913, a stage control part 914, and the like are thereby implemented by software. Further, at least some of these function blocks may be implemented by dedicated hardware.

The exposure data generation part 911 generates exposure data to be used for modulating a light beam in accordance with a pattern, on the basis of the CAD data 932 read out from the storage 93. When the substrate S has deformation such as distortion or the like, the exposure data generation part 911 corrects the exposure data in accordance with the amount of distortion of the substrate S, to thereby enable drawing in accordance with the shape of the substrate S. The exposure data is sent to the exposure head 41, and the exposure head 41 modulates the laser light emitted from the light irradiation part 40 in accordance with the exposure data. The modulated light beam which is thus modulated in accordance with the pattern is emitted onto the substrate S and the surface of the substrate S is partially exposed, to thereby draw the pattern thereon.

The exposure control part 912 controls the light irradiation part 40 to emit a laser light beam having predetermined power and a spot size. The focus control part 913 controls a projection optical system (described later) provided in the exposure head 41 to converge the laser light beam on the surface of the substrate S.

The stage control part 914 controls the stage driving mechanism 3 to achieve movement of the stage 2 for alignment adjustment and movement of the stage 2 for scanning movement during exposure. In the alignment adjustment, the position of the stage 2 is adjusted in the X direction, the Y direction, the Z direction, and the 0 direction so that a relative positional relation between the substrate S placed on the stage 2 and the exposure head 41 at the start of exposure can be a relation determined in advance. On the other hand, in the scanning movement, by causing the stage 2 to move in the Y direction at a constant speed, a main scanning movement in which the substrate S is caused to pass below the exposure head 41 and a step feed (sub-scanning movement) in which the substrate S is moved in a constant pitch in the X direction are combined.

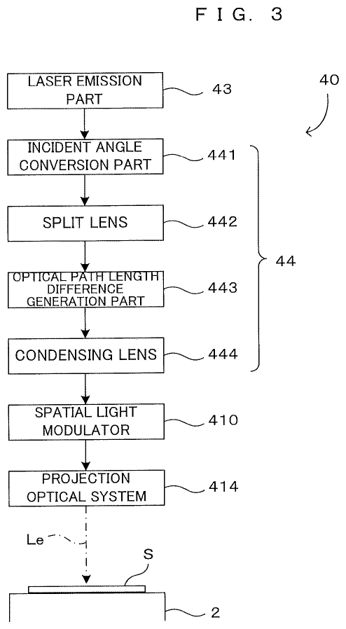

FIG. 3 is a view showing an outline configuration of the light irradiation part. The light irradiation part 40 includes optical elements such as an incident angle conversion part 441, a split lens 442, an optical path length difference generation part 443, a condensing lens 444, a projection optical system 414, and the like, as main constituent elements other than the laser emission part 43 and the spatial light modulator 410. The incident angle conversion part 441, the split lens 442, the optical path length difference generation part 443, and the condensing lens 444 constitute the illumination optical system 44 as a unit.

The laser light beam emitted from the laser emission part 43 enters the split lens 442 through the incident angle conversion part 441 and further enters the optical path length difference generation part 443. As described later, the light emitted from the optical path length difference generation part 443 is a light beam having a flattened spot shape with a long axis direction which is the horizontal direction (X direction). The light beam is further narrowed in a short axis direction by the condensing lens 444 to form a line light beam, and the line light beam enters the spatial light modulator 410 of the exposure head 41. The light emitted from the spatial light modulator 410 is a light beam modulated in accordance with the exposure data and this light beam is emitted onto the substrate S on the stage 2 through the projection optical system 411.

A detailed structure of the illumination optical system 44 will be described later, but first, a structure of the exposure head 41 in the light irradiation part 40 will be described herein.

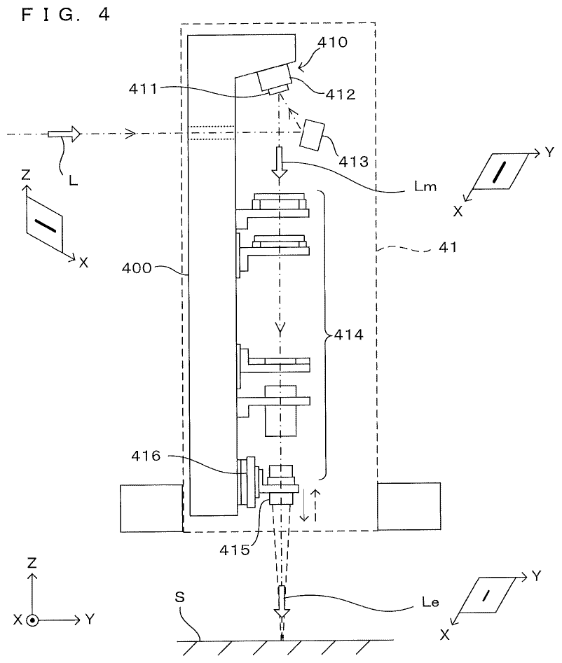

FIG. 4 is a view schematically showing an exemplary detailed configuration included in the exposure head. As shown in FIG. 4, in the exposure head 41, the spatial light modulator 410 having a diffractive optical element 411 is provided. Specifically, the spatial light modulator 410 attached on an upper portion of a column 400 extending in an up-and-down direction (Z direction) in the exposure head 41 is supported by the column 400 with a movable stage 412 interposed therebetween, with a reflection surface of the diffractive optical element 411 facing downward.

In the exposure head 41, the diffractive optical element 411 is disposed with a normal of the reflection surface thereof inclined with respect to a traveling direction of an incident light beam L. The light outgoing from the illumination optical system 44 is incident on a mirror 413 through an opening of the column 400 and reflected by the mirror 413, to be emitted onto the diffractive optical element 411. Then, a state of each channel of the diffractive optical element 411 is switched by the controller 9 in accordance with the exposure data, and the laser light beam L incident on the diffractive optical element 411 is modulated.

While the laser light reflected from the diffractive optical element 411 as zero-order diffracted light is incident on a lens of the projection optical system 414, the laser light reflected from the diffractive optical element 411 as first or higher-order diffracted light is not incident on a lens of the projection optical system 414. In other words, basically, only the zero-order diffracted light reflected by the diffractive optical element 411 enters the projection optical system 414. The diffractive optical element 411 is arranged so that the zero-order diffracted light can be emitted in a (−Z) direction. As the diffractive optical element 411, a GLV (Grating Light Valve) element manufactured by Silicon Light Machines Corp. (“GLV” is a registered trademark of this company) can be suitably applied.

The light which has passed through the lens of the projection optical system 414 is converged by a focusing lens 415 and guided onto the substrate S with a predetermined magnification, as an exposure beam having a traveling direction which is the (−Z) direction, i.e., facing downward. The projection optical system 414 forms a reduction optical system. This focusing lens 415 is attached to a focus driving mechanism 416. Then, in response to a control command from the focus control part 913 of the controller 9, the focus driving mechanism 416 moves the focusing lens 415 up and down along a vertical direction (Z-axis direction). By this operation, a convergence position of the exposure beam emitted from the focusing lens 415 is adjusted onto the upper surface of the substrate S.

As shown along an optical path of the laser light beam L indicated by a one-dot chain line in FIG. 4, the laser light beam L guided from the light irradiation part 40 to the exposure head 41 has a beam spot shape which is thinly elongated uniformly in the X direction, with the X direction as a long axis direction and the Z direction as a short axis direction. On the other hand, a modulated laser light beam Lm after being modulated by the spatial light modulator 410 has a long axis direction which is the X direction and a short axis direction which is the Y direction and a light intensity distribution in the X direction is modulated in accordance with the exposure data. Further, the exposure beam Le emitted from the projection optical system 414 toward the substrate S is a beam obtained by reducing the modulated laser light beam Lm in the X direction and the Y direction. By causing the exposure beam Le having a spot size narrowed thus to be incident on an exposed surface of the substrate S, a fine pattern can be drawn on the surface of the substrate S.

The exposure head 41 and the substrate S are relatively moved in the Y direction while the exposure beam Le modulated in accordance with the exposure data is caused to be incident on the substrate S. By this operation, out of the substrate S, a strip-like region extending in the Y direction and having the same width as the spot size of the exposure beam Le in the X direction can be exposed. By performing exposure repeatedly while sequentially changing the relative position between the exposure head 41 and the substrate S in the X direction, it is possible to expose the entire substrate S in the end.

Thus, by combining the scanning movement in the Y direction and the scanning movement in the X direction between the exposure head 41 and the substrate S, it is possible to draw the entire substrate S. In the present specification, the scanning movement in the Y direction is referred to as a “main scanning movement” and the Y direction is referred to as a “main scanning direction”. On the other hand, the scanning movement in the X direction is referred to as a “sub-scanning movement” and the X direction is referred to as a “sub-scanning direction”. In this embodiment, by moving the stage 2 supporting the substrate S with respect to the fixed exposure head 41, these scanning movements can be achieved.

A plurality of exposure units 4 each having the above-described configuration can be provided at different positions in the X direction. In this embodiment, five sets of exposure units 4 which have the same configuration are provided, and these sets of exposure units 4 emit exposure beams Le in parallel to perform drawing, to thereby ensure an increase in the throughput of the drawing operation. Further, each of the exposure units 4 can operate independently of one another, but these scanning movements relative to the substrate S are uniformly performed for structural reasons.

Next, in the light irradiation part 40, the configurations of the laser emission part 43 and the illumination optical system 44 will be described.

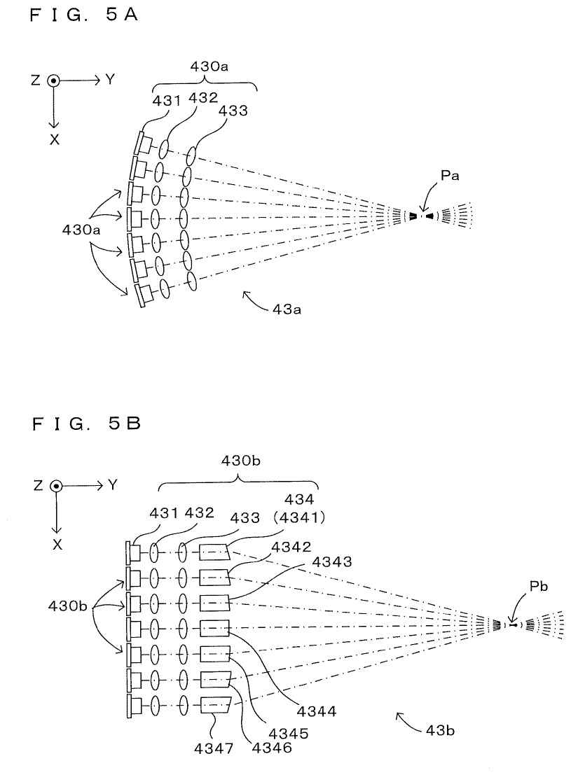

FIGS. 5A and 5B are views each showing an outline configuration of the laser emission part. As shown in FIGS. 5A and 5B, as the configuration of the laser emission part 43, for example, some aspects are possible. A laser emission part 43a having an exemplary configuration shown in FIG. 5A includes a plurality of light source units 430a. Though seven sets of light source units 430a are used herein, the number of arranged light source units is not limited to this number but arbitrarily set.

Each light source unit 430a has a laser light source 431 for emitting laser light, a collimator lens 432, and a condensing lens 433. The laser light source 431 is, for example, a laser diode which outputs laser light having a predetermined wavelength. The collimator lens 432 converts the laser light emitted from the laser light source 431 into collimated light. The condensing lens 433 condenses the collimated laser light to be outputted as a convergent light beam.

As indicated by a one-dot chain line in the figure, the light source units 430a are arranged so that respective outgoing light beams should intersect at one point. Specifically, the light source units 430a are arranged so that respective centerlines of outgoing lights thereof indicated by one-dot chain lines should go along the same XY plane and intersect at one point Pa in this XY plane.

On the other hand, in the laser emission part having an exemplary configuration shown in FIG. 5B, provided is a light source unit 430b having the laser light source 431, the collimator lens 432, and the condensing lens 433 which are the same as those in the above-described exemplary configuration. The laser light sources 431 each emit laser light in the same direction (Y direction in this exemplary case) in the same XY plane. In other words, the laser lights emitted from the laser light sources 431 are in parallel to one another.

On each optical axis, a wedge prism 434 (4341 to 4347) is provided. Respective end surfaces on the (+Y) side of the wedge prisms 4341 to 4347 are set to each have a tilt with respect to the XY plane so that the respective outgoing lights should intersect at one point Pb in the XY plane. An error caused by deviation from the parallel line of the laser light emitted from each laser light source 431 can be adjusted by moving the condensing lens 433 and the wedge prism 434 in the Y direction. By such an operation, it is possible to cancel the deviation from the one point Pb in the XY plane.

As the laser emission part 43, both the two exemplary configurations 43a and 43b described above can be suitably applied. For this reason, in the following description, these laser emission parts are not particularly distinguished from each other but will be described as the “laser emission part 43”. Even when the configuration exemplarily shown in this figure corresponds to either of the above-described exemplary configurations 43a and 43b, it is just exemplarily shown and the other exemplary configuration, instead of the above-described exemplary configuration, can be applied without any problem.

Further, from the viewpoint of component manufacturing, the configuration of FIG. 5B in which the laser light sources 431 are linearly arrayed in a row is advantageous. In a case where the number of laser light sources 431 which are provided is large, particularly, in the configuration of FIG. 5A in which it is necessary to arrange the laser light sources 431 at an appropriate angle, there is a possibility that an adjustment operation may be complicated. Further, also in a case where a water cooling mechanism for cooling the light source is provided, the configuration in which the laser light sources 431 are linearly arrayed is advantageous. Furthermore, it is desirable that the arrangement of the laser light sources 431 in the XY plane should be symmetric with respect to the optical axis of the illumination optical system 44.

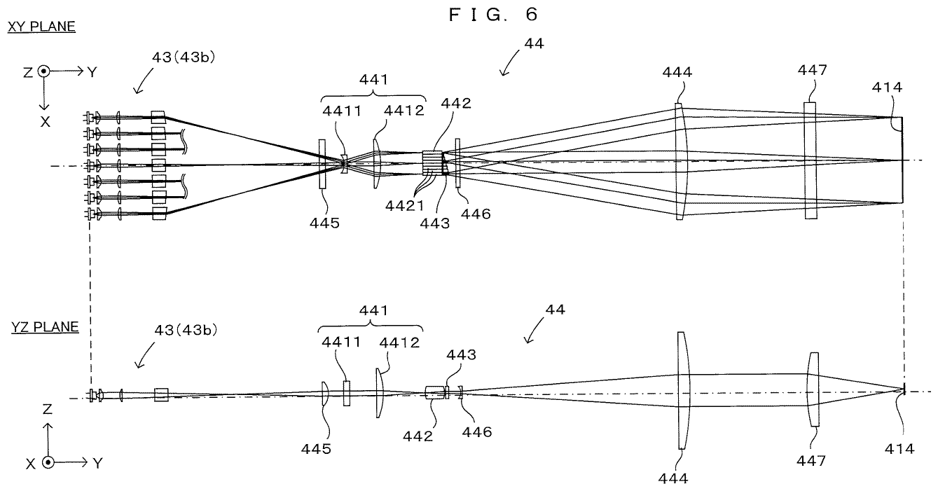

FIG. 6 is a light ray diagram showing an overall configuration of the illumination optical system and the optical path of the light beams. More specifically, FIG. 6 shows a configuration of the illumination optical system 44 in the XY plane and that in the YZ plane. Note that, when a light ray diagram is shown in FIG. 6 and the following figures, some rays of light are omitted for easier viewing. Specifically, in FIG. 6, for example, among the lights emitted from the seven sets of laser light sources 431, only the outgoing lights from the center one and two on both ends are shown.

The illumination optical system 44 includes a Z-direction collimator lens 445, a Z-direction diffuser lens 446, a Z-direction condensing lens 447, and the like, as well as the above-described main constituent elements, i.e., the incident angle conversion part 441, the split lens 442, the optical path length difference generation part 443, and the condensing lens 444. These optical elements are arranged so that the respective optical axes thereof should coincide with one another. In FIG. 6, the optical axis is represented by a one-dot chain line.

The plurality of laser light beams emitted from the laser emission parts 43 enter the incident angle conversion part 441 provided near an intersection point thereof. Specifically, the collimator lens 445 is provided on the frontward side relative to the intersection point, i.e., on a side nearer to the laser emission parts 43 and the light beam having passed through the lens 445 enters the incident angle conversion part 441. The collimator lens 445 is, for example, a cylindrical lens having no power in the X direction and having power in the Z direction. Therefore, in the Z direction, the laser light beam is collimated.

In the incident angle conversion part 441, a concave lens 4411 is disposed on the frontward side relative to the intersection point of the laser light beams and at a position where the laser light beam emitted from each light source unit 430 can enter. The concave lens 4411 has power in the X direction and does not have power in the Z direction. Further, in a rear direction of the concave lens 4411 in the optical path of the laser light beam, a convex lens 4412 is disposed. As described next, the convex lens 4412 is arranged at such a position as to form a beam expander with the concave lens 4411.

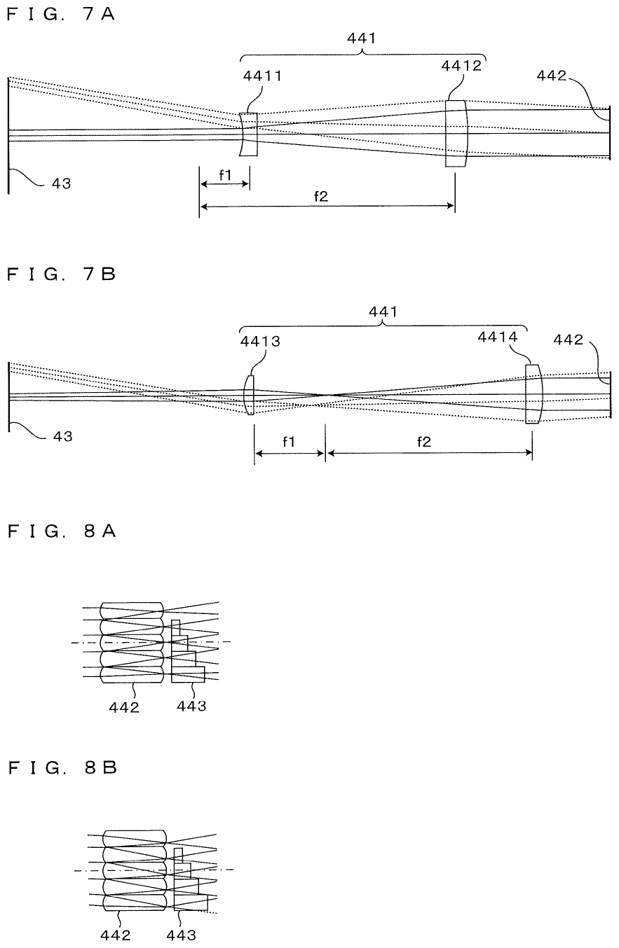

FIGS. 7A and 7B are views each showing a more detailed configuration and an action of the incident angle conversion part. The incident angle conversion part 441 of the present embodiment has a configuration shown in FIG. 7A. When a focal length of the concave lens 4411 is represented as f1 and that of the convex lens 4412 is represented as f2, both lenses have such a positional relation as shown in FIG. 7A. Specifically, the convex lens 4412 is arranged so that a front focus position thereof can coincide with a focus position of the concave lens 4411.

Such a combination of the lenses corresponds to a configuration referred to as a Galilean beam expander. The beam expander is generally used to enlarge (or reduce) the beam diameter of the collimated light incident along the optical axis. On the other hand, in this embodiment, as shown in the light ray diagram of FIG. 7A, lights enter the concave lens 4411 from the laser emission parts 43 from a plurality of directions, and the incident direction is not necessarily along the optical axis.

In such conditions, the light incident on the concave lens 4411 with a relatively large spread angle is once diffused by the concave lens 4411 and then condensed by the convex lens 4412. The spread angle of the outgoing lights becomes smaller than that of the incident lights. Thus, the lights whose spread angle is suppressed enter the split lens 442. In other words, the incident angle conversion part 441 has an action of reducing the spread of the incident lights as viewed from the split lens 442 and quantitatively reducing the maximum incident angle of the incident lights incident on the split lens 442.

With reference back to FIG. 6, description of the illumination optical system 44 will continue. Respective configurations of the split lens 442 and the optical path length difference generation part 443 are the same as those disclosed in Patent Literature 1. Specifically, the split lens (fly eye lens) 442 has a plurality of lenses 4421 arranged in the X direction and perpendicular to the optical axis and splits the light emitted from the incident angle conversion part 441 by using the plurality of lenses 4421. On the other hand, the optical path length difference generation part 443 has a plurality of light-transmitting parts arrayed in a direction perpendicular to the optical axis and having different optical path lengths, to cause the lights which have passed through the split lens 442 to enter the plurality of light-transmitting parts, respectively. Since these configurations and actions are described in detail in Patent Literature 1 (Patent Publication No. 6383166), description thereof will be omitted herein. In short, these constituent elements, as a unit, have a function of splitting the incident beam light into a plurality of beams arranged in a constant pitch in the X direction and adjusting respective optical path lengths thereof.

FIGS. 8A and 8B are light ray diagrams each showing light passing through the split lens and the optical path length difference generation part. In the exemplary case shown in FIG. 8A, the lights entering the split lens 442 from an end surface on the (−Y) side exit from an end surface on the (+Y) side of the split lens 442 and an end surface on the (+Y) side of the optical path length difference generation part 443. On the other hand, in the exemplary case shown in FIG. 8B, some of the lights entering the optical path length difference generation part 443 exit from the side surface thereof, not reaching the end surface on the (+Y) side and being dissipated. In a case where the maximum incident angle of the light entering the split lens 442 is large, such dissipation of the light occurs. The dissipation of the light which is caused thus deteriorates the light intensity on the whole and also deteriorates the uniformity of the light intensity in the X direction.

In a case where the number of laser light sources 431 is increased in order to increase the light intensity, due to the configuration in which the laser light sources 431 are aligned in the X direction, it is inevitable that the incident angle of the light from the laser light source 431 disposed at an end portion into the split lens 442 disadvantageously becomes larger. In other words, the spread angle of the incident light on the split lens 442 becomes larger.

By providing the incident angle conversion part 441 between the laser emission part 43 and the split lens 442, it becomes possible to reduce the spread angle of the incident lights on the split lens 442 to be smaller and approximate the lights to parallel lights. As a result, it is possible to suppress the dissipation of the lights due to the spread of the incident lights described above. An exemplary case where light having a tilt of about 9 degrees at the maximum with respect to the optical axis enters the incident angle conversion part 441 is considered. At that time, when the concave lens 4411 of f1=−11 mm and the convex lens 4412 of f2=100 mm are used, it is possible to cause the light having a tilt of about 1 degree at the maximum with respect to the split lens 443 to be incident on the split lens 443 from the incident angle conversion part 441.

Further, the incident angle conversion part 441 has an action of adjusting the X-direction spot size of the light beam formed of these lights on the whole to the size adaptable to the size of the split lens 442, additionally to the action of converting the lights from the plurality of laser light sources 431 into almost parallel lights on the whole. In other words, the incident angle conversion part 441 has the action of causing the lights to be uniformly incident on the plurality of lenses 4421 constituting the split lens 442, respectively. This can be said that this is the action as the beam expander which can appropriately enlarge or reduce the spot size of the incident light beam.

In terms of suppressing the spread angle of the incident light, the same effect can be produced also by increasing the distance between the laser emission part 43 and the split lens 442 and reducing the incident angle. In this case, since the optical path length becomes longer, it is inevitable that an overall size of the illumination optical system 44 disadvantageously becomes larger. The incident angle conversion part 441 of the present embodiment is more preferable since the incident angle can be reduced without increasing the optical path length.

Note that, as the beam expander, besides the above-described Galilean-type one, there is a Keplerian-type one in which two convex lenses are combined. As the incident angle conversion part 441, such a Keplerian-type one can be applied. That is, as shown in FIG. 7B, a convex lens 4413 is disposed at a position where the plurality of light beams emitted from the laser emission parts 43 can be incident, in a rear direction relative to the intersection point of the light beams. The convex lens 4413 has power at least in the X direction.

Then, another convex lens 4414 is arranged so that a front focus position thereof should become a back focus position of the convex lens 4413. The convex lens 4414 has power at least in the X direction. The reference signs f1 and f2 in FIG. 7B represent focal lengths of the convex lenses 4413 and 4414, respectively. Thus, a Keplerian beam expander is formed. Even in such a configuration, as shown in the light ray diagram of FIG. 7B, the light emitted from the laser emission part 43 with a relatively large spread angle can be caused to be incident on the split lens 442 as light having a smaller spread angle.

Comparison between the respective configurations shown in FIGS. 7A and 7B is as follows. The configuration shown in FIG. 7A has an advantage of reducing the optical path length if the lens magnification is the same and being less susceptible to a dust or the like on the optical path since the beam is not converged. On the other hand, the configuration shown in FIG. 7B has an advantage of being achieved by combination of convex lenses and easily making adjustment since the beam is converged between the lenses in this configuration.

Further, in the incident angle conversion part 441, in order to cause the enlargement (or reduction) magnification of the beam between the incident light and the outgoing light to be a desirable value, it is necessary that the arrangement of two lenses is so set as to satisfy configuration requirements of the Galilean or Keplerian beam expander in accordance with the focal lengths. On the other hand, for the purpose of simply adjusting the spread angle of the light beam, variation of the arrangement of lenses is allowed to some degree. In other words, the arrangement of two lenses may not strictly satisfy the requirements of the beam expander.

Further, it can be thought that the purpose of adjusting the spread angle of the beam can be achieved even with a single concave lens. As described next, however, an excellent result cannot be necessarily achieved by incident angle conversion using a single lens.

By appropriately setting lens characteristics, even with a single concave lens, it is possible to convert the incident light into almost parallel light and suppress the spread angle. Actually, however, when it is intended to suppress the spread of the light having passed through the concave lens, the curvature of a lens curved surface cannot be made so large. Then, a ratio of the spot size of the incident light beam to that of the outgoing light beam does not necessarily become large. Each of the light beams emitted from the laser emission part 43 enters the split lens 442 without being enlarged so much. In general, each beam spot in this case is sufficiently smaller than the diameter of each of the lenses constituting the split lens 442. Therefore, it becomes hard to achieve the purpose of uniformly causing the light to be incident on each lens.

For this reason, the present embodiment uses the principle of the beam expander formed by combination of two lenses. In such a configuration, the effect of incident angle conversion (reduction in the spread angle) and the controllability thereof are excellent. Further, by appropriately selecting the lens magnification, it becomes easier to adjust the beam spot size.

With reference back to FIG. 6 again, the light beam emitted from the optical path length difference generation part 443 enters the Z-direction diffuser lens 446. The Z-direction diffuser lens 446 is a concave lens not having power in the X direction and having power in the Z direction. Therefore, the Z-direction diffuser lens 446 emits light beams to be diffused in the Z direction.

These light beams are incident on an image surface through the condensing lens 444 and the Z-direction condensing lens 447. The image surface in this case is a light receiving surface of the diffractive optical element 414. The condensing lens 444 is a convex lens having power both in the X direction and the Z direction, and converges the light beams onto the image surface. The plurality of light beams emitted from the split lens 442 and aligned in the X direction are superimposed on the image surface. Since these light beams are coherent lights, an interference of these lights can occur in the superimposition. The optical path length difference generation part 443 makes a difference in the optical path lengths of the light beams, to thereby avoid occurrence of the interference.

On the other hand, in the Z direction, the light beams are once enlarged by the Z-direction diffuser lens 446 and then significantly narrowed by the two condensing lenses 444 and 447. As a result, a line light beam L (FIG. 4) having a flattened shape in the X direction and uniform intensity, whose spread in the Z direction is small, is incident on the image surface (diffractive optical element 414). As shown in FIG. 4, this line light beam L is modulated by the diffractive optical element 414 of the spatial light modulator 410. The modulated light beam Lm is reduced by the projection optical system 414 and emitted onto the substrate S as the exposure beam Le.

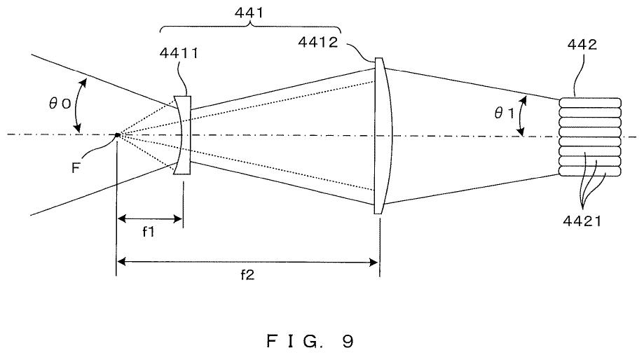

Next, optical characteristics required for the incident angle conversion part 441 will be described with reference to FIG. 9. FIG. 9 is a view showing a relation between the incident light on the incident angle conversion part and that on the split lens. As shown in FIG. 9, the maximum incident angle allowed for the incident light on the split lens 442 may be represented by the reference sign θ1. Herein, the maximum incident angle θ1 is the maximum value of the incident angle of light emitted from the optical path length difference generation part 443 without dissipation of the light incident on the split lens 442. In other words, in order to prevent dissipation of the light, it is necessary that the incident angle of the incident light on the split lens 442 should be not larger than the maximum incident angle θ1. The maximum incident angle θ1 depends on the diameter and the length of each of lenses constituting the split lens 442 and the length of the optical path length difference generation part 443.

In order that the incident angle of the light incident on the split lens 442 from the incident angle conversion part 441 should be not larger than the maximum incident angle θ1, the condition that the incident angle θ0 of the incident light on the incident angle conversion part 441 should satisfy is expressed as the next formula:

$$θ 1 \geq 1 / \vert f 2 / f 1 \vert \times θ0 = \vert f 1 / f 2 \vert \times θ0 , \qquad ( Eq . 1 )$$

or this formula is transformed as follows:

$$θ0 \leq \vert f 2 / f 1 \vert \times θ1 . \qquad ( Eq . 2 )$$

When the equal sign is satisfied, the allowed value of the incident angle on the incident angle conversion part 441 from the laser emission part 43 can be made the maximum. The respective focal lengths f1 and f2 of the two lenses 4411 and 4412 have only to be set so that this condition is satisfied and such an appropriate enlargement (or reduction) magnification can be achieved, as to obtain a beam spot size with which the lights can be uniformly incident on the lenses constituting the split lens 442. In this figure, the reference sign F represents a focal point of the two lenses 4411 and 4412.

As described above, in this embodiment, the laser lights emitted from the plurality of laser light sources 431 aligned in the X direction are superimposed on one another by the illumination optical system 44. The line light beam L having a flattened beam spot shape with the X direction as the long axis direction is thereby generated. Between the plurality of laser light sources 431 and the split lens 442, the incident angle conversion part 441 for reducing the incident angle on the split lens 442 is provided.

Even in a case where the number of provided laser light sources 431 is large and the spread angle of the light emitted therefrom thereby becomes larger, it is possible to reduce the incident angle on the split lens 442 to be smaller. In this embodiment, it is thereby possible to reliably guide the light beam emitted from the laser light source 431 to the end surface on the outgoing side (+Y side) of the split lens 442 and the optical path length difference generation part 443 and prevent the dissipation of light from the side surface. As a result, it is possible to generate a line light beam having high intensity and uniform intensity distribution.

The incident angle conversion part 441 can be achieved by combination of the concave lens 4411 and the convex lens 4412 or combination of the convex lens 4413 and the convex lens 4414, which have a common optical axis. The two lenses are arranged in such a positional relation as to satisfy the condition to form a beam expander. By using such an optical system on the condition that the light is incident also from a diagonal direction with respect to the optical axis, it is possible to cause the spread of the outgoing light, i.e., the incident angle on the post stage to become smaller than the incident angle of the incident light on the optical system.

Further, the incident angle conversion part 441 has a function as the beam expander and can cause the light adjusted to have an appropriate spot size to be incident on the post-stage split lens 442. For this reason, it is possible to cause the light to be uniformly incident on the lenses 4421 constituting the split lens 442. Since the outgoing lights therefrom are combined, it is possible to cause the light quantity distribution in the long axis direction of the line light beam which is finally generated to be uniform.

As described above, in the exposure apparatus 1 of the embodiment, the light irradiation part 40, the spatial light modulator 410, the projection optical system 414 and the controller 9 function as “a light irradiation part”, “a light modulator”, “a projection optical system” and “a controller” of the invention, respectively. Further, the light irradiation part 40 corresponds to “a light irradiation apparatus” of the invention.

Further, the illumination optical system 44 including the laser light source 431, the incident angle conversion part 441, the split lens 442, the optical path length difference generation part 443 and the condensing lens 444 functions as “a illumination optical system” of the invention. Further, the collimator lens 445 and the diffuser lens 446 function as “a collimator lens” and “a diffuser lens” of the invention, respectively.

Furthermore, in the incident angle conversion part 441, the concave lens 4411 and the convex lens 4413 correspond to “a first lens” of the invention, while the convex lens 4412, 4414 correspond to “a second lens” of the invention. Further, XY plane in the above embodiment corresponds to “a plane” of the invention.

Note that the invention is not limited to the above embodiments and various changes other than the aforementioned ones can be made without departing from the gist of the invention. In the above-described embodiment, for example, the number of laser light sources 431 arranged in the laser emission part 43 is seven but not limited to this number. In a case where the number of laser light sources is small, the incident angle conversion part does not necessarily need to be provided since the spread of the light can be inevitably reduced to be smaller, but in a case where the number of laser light sources is large, the present invention is particularly effective.

Further, in order to further increase the beam light intensity, there is a possible method in which a plurality of laser light sources are arranged also in the Z direction. As an exemplary configuration in this case, the lights from the plurality of laser light sources provided in the Z direction are combined to form one light beam along the XY plane by an appropriate optical system and further a plurality of such light beams are combined in the XY plane. In such a case, by handling each of the light beams combined in the Z direction in the same manner as the outgoing light beam from each laser emission part 43 in the above-described embodiment, even a configuration in the case where the present invention is applied can be thought of.

Further, though the GLV element which is a one-dimensional diffractive optical element can be suitably applied as the “light modulator” of the present invention in the above-described embodiment, elements other than this element can be applied as the light modulator. For example, a two-dimensional diffractive optical element, a DMD (Digital Micro mirror Device) element in which a lot of minute mirrors are arrayed to control reflection, and the like can be used as the light modulator.

Furthermore, the exposure apparatus 1 of the above-described embodiment incorporates the light irradiation part 40 which corresponds to a “light irradiation apparatus” of the present invention, but it can be thought that only the light irradiation part 40 is the embodiment of the present invention. For example, the light irradiation part in the already-existing exposure apparatus is replaced by the light irradiation part of the present embodiment, or modified like the light irradiation part 40 of the present embodiment, and the present invention can be thereby carried out.

Thus, as described above by taking the specific embodiment as an example, the incident angle conversion part of the light irradiation apparatus in accordance with the present invention can be achieved by either combination of the concave lens and the convex lens or combination of the convex lens and the convex lens, as the combination of the first lens and the second lens. As the combination of the concave lens and the convex lens, the configuration of the so-called Galilean beam expander can be applied. As the combination of the convex lens and the convex lens, the configuration of the so-called Keplerian beam expander can be applied. With either one of these combinations, it is possible to reduce the incident angle of the light on the split lens part and suppress the dissipation of light from the split lens part and the optical path length difference generation part.

Further, for example, the first lens may be a lens having no power in a direction orthogonal to the plane. The incident angle conversion part is provided for the purpose of adjusting the incident angle in a direction along the above-described plane, and may be an element which has no action on the direction orthogonal to the plane. Therefore, designing of the optical system in the direction along the plane and that in the direction orthogonal to the plane can be performed independently of each other, and the degree of freedom in the design increases.

Furthermore, for example, the arrangement of the plurality of laser light sources can be symmetric with respect to the optical axis in the plane. By causing the light incident on the first lens, being inclined with respect to the optical axis, to be incident on the lens from a direction symmetric with respect to the optical axis, the uniformity of the light in the plane can be increased.

Further, for example, the collimator lens having power in the direction orthogonal to the plane may be disposed between the laser light source and the incident angle conversion part. With such a configuration, it is possible to suppress diffusion of the light in the direction orthogonal to the plane and reliably guide the outgoing light from the laser light source to the incident angle conversion part and the split lens part.

In this case, for example, the diffuser lens having power in direction orthogonal to the plane may be disposed between the optical path length difference generation part and the condensing lens. With such a configuration, by once diffusing the light in the direction orthogonal to the plane before the condensing lens, it is possible to significantly narrow the light in direction orthogonal to the plane in the end.

Further, when the spread angle of the outgoing lights from the plurality of laser light sources, which is viewed from the first lens, is θ1, the maximum value of the incident angle of the light which is incident on the split lens part and can pass through the optical path length difference generation part is 00, the focal length of the first lens is f1, and the focal length of the second lens is f2, the following relation may be satisfied:

θ1≥|f1/f2|×θ0.

Thus, it is possible to emit the light from an outgoing end of the optical path length difference generation part without dissipation of the light incident from the laser light source. In the above-described formula, an equal sign indicates the condition on which 00 becomes the maximum value allowed as the incident angle of the light on the first lens. In other words, when the maximum incident angle θ0 from the plurality of laser light sources is determined in advance, by selecting the first lens and the second lens so that the above-described formula is satisfied, it becomes possible to suppress the dissipation of light in the post stage.

Although the invention has been described with reference to specific embodiments, this description is not meant to be construed in a limiting sense. Various modifications of the disclosed embodiment, as well as other embodiments of the present invention, will become apparent to persons skilled in the art upon reference to the description of the invention. It is therefore contemplated that the appended claims will cover any such modifications or embodiments as fall within the true scope of the invention.

### INDUSTRIAL APPLICABILITY

This invention is suitable for technical fields for exposing a substrate such as a semiconductor substrate, a semiconductor package substrate, a printed circuit board, a glass substrate, or the like to form a pattern on the substrate.

### REFERENCE SIGNS LIST

1 exposure apparatus
2 stage
9 controller
40 light irradiation part
410 spatial light modulator
414 projection optical system
431 laser light source
441 incident angle conversion part
442 split lens
443 optical path length difference generation part
444 condensing lens
445 collimator lens
446 diffuser lens
4411 concave lens (first lens)
4412 convex lens (second lens)
4413 convex lens (first lens)
4414 convex lens (second lens)
L laser light beam
Le exposure light beam
S substrate

1. A light irradiation apparatus, comprising:
a plurality of laser light sources arranged so that respective centerlines of outgoing lights thereof are included in the same plane and intersect at one point in the plane; and
an illumination optical system which combines laser lights emitted from the plurality of laser light sources to form a single laser light beam and emits the single laser light beam onto an irradiated surface,
wherein the illumination optical system includes:
an incident angle conversion part which has a first lens arranged at a position on which respective lights emitted from the plurality of laser light sources are incident and a second lens arranged in such a positional relation as to form a beam expander with the first lens;
a split lens part which has a plurality of lenses arrayed in a direction perpendicular to an optical axis of the incident angle conversion part and along the plane and splits light emitted from the incident angle conversion part by the plurality of lenses;
an optical path length difference generation part which has a plurality of light-transmitting parts which have different optical path lengths and are arrayed in the direction perpendicular to the optical axis and causes the lights passed through the plurality of lenses to enter the plurality of light-transmitting parts, respectively; and
a condensing lens part which superimposes irradiation regions of the lights emitted from the plurality of light-transmitting parts on the irradiated surface.

2. The light irradiation apparatus according to claim 1, wherein
the first lens is a concave lens and the second lens is a convex lens.

3. The light irradiation apparatus according to claim 1, wherein
the first lens and the second lens are convex lenses.

4. The light irradiation apparatus according to claim 1, wherein
the first lens has no power in a direction orthogonal to the plane.

5. The light irradiation apparatus according to claim 1, wherein
arrangement of the plurality of laser light sources is symmetric with respect to the optical axis in the plane.

6. The light irradiation apparatus according to claim 1, wherein
a collimator lens having power in a direction orthogonal to the plane is arranged between the laser light source and the incident angle conversion part.

7. The light irradiation apparatus according to claim 6, wherein
a diffuser lens having power in the direction orthogonal to the plane is arranged between the optical path length difference generation part and the condensing lens part.

8. The light irradiation apparatus according to claim 1, wherein
when a spread angle of outgoing lights from the plurality of laser light sources, which is viewed from the first lens, is θ1, the maximum value of an incident angle of light which is incident on the split lens part and can pass through the optical path length difference generation part is 00, a focal length of the first lens is f1, and a focal length of the second lens is f2, the following relation is satisfied:
θ1≥|f1/f2|×θ0.

9. An exposure apparatus for exposing a surface of a substrate to draw a predetermined pattern thereon, comprising:
a light irradiation part having a same configuration as that of a light irradiation apparatus according to claim 1;
a light modulator arranged at a position on the irradiated surface;
a controller which controls the light modulator on the basis of exposure data representing a pattern to be drawn to modulate the laser light beam; and
a projection optical system which causes the modulated laser light beam to be incident on the substrate.
